(19) United States
(12) Patent Application Publication
(10) Pub. No.: US 2011/0014446 A1
(43) Pub. Date: Jan. 20, 2011

(54) METHOD FOR FORMING CARBON NANOTUBE FILM, FILM-FORMING APPARATUS, AND CARBON NANOTUBE FILM

(76) Inventor: Takeshi Saito, Ibaraki (JP)

Correspondence Address: J C PATENTS, 4 VENTURE, SUITE 250, IRVINE, CA, 92618, US

(21) Appl. No.: 12/667,830

(22) PCT Filed: Jul. 1, 2008
(86) PCT No.: PCT/JP2008/061917

§ 371 Date: Jan. 5, 2010

(30) Foreign Application Priority Data
Jul. 6, 2007 (JP) 2007-178585
Jul. 1, 2008 (JP) PCT/JP2008/061917

(51) Int. Cl. C23C 16/26

(52) U.S. Cl. 428/220; 427/189; 118/724; 977/902

(57) ABSTRACT

A method and an apparatus for efficiently mass-producing a single-wall carbon nanotube (SWCNT) film are disclosed. The SWCNT film is useful as an industrial material, at low temperature and low cost. The method and apparatus are characterized in that carbon nano-tubes (CNTs) are synthesized from a raw material source through a gas-phase chemical vapor deposition (CVD) process, and the synthesized CNTs are directly deposited on a substrate in a chamber connected with a reaction tube, thereby forming a CNT film on the substrate.

### BACKGROUND OF THE INVENTION

1. Field of the Invention

The present invention generally relates to a method and an apparatus for forming a carbon nanotube (CNT) film containing single-wall carbon nanotubes (SWCNTs), and a CNT film, in particular, to a method and an apparatus for mass-producing a carbon nanotube (CNT) film from a raw material source at a low temperature of 200° C. or less at low cost through a gas-phase chemical vapor deposition (CVD) process, and a film.

2. Description of Related Art

A nanotube is a tube-shaped molecule formed by a network of chemical bonds, and a typical nanotube is a CNT in a tube-shaped network structure formed of graphite carbon. The CNT produced for the first time in 1991 was a multiwall carbon nanotube (MWCNT), and a single-wall carbon nanotube (SWCNT) was produced in 1993. Thereafter, the discovery of BNC nanotubes and BN nanotubes, in which boron (B) or nitride (N) was substituted for a portion or all of carbon atoms, was also reported.

The CNT is characterized by, a length of tens of nm to tens of μm, a diameter of 0.4 nm to 5 nm (SWCNT) or 2 nm to 100 nm (MWCNT), and a tiny elongated shape. Moreover, it is clear that the SWCNT can function as either a conductor (metal) or a semiconductor depending on its three-dimensional structure. Particularly, the CNT in the semiconductor structure has the following characteristics: the width of its forbidden band (energy band gap) is inversely proportional to the diameter of the tube, and can be continuously changed from about 1 eV through structural control. Other semiconductors, such as silicon semiconductors do not have the above-mentioned characteristics, and these characteristics indicate the possibility of designing semiconductor devices having various properties and a high degree of freedom.

The CNT synthesis processes may be approximately classified into the following three categories, namely, an arc discharge process (see Patent Document 1), a laser evaporation process (see Non-patent Document 1), and a CVD process (see Patent Document 2).

The CVD process is suitable for efficient mass production at low cost, and may be approximately categorized into a substrate CVD process and a gas-phase CVD process. In the substrate CVD process, CNTs are produced by growing a catalyst carried by a substrate or a carrier; in the gas-phase CVD process, a carbon-containing raw material containing a catalyst precursor or a catalyst with a very small particle size is atomized by using a spray or the like, and is introduced into a high-temperature electric furnace, so as to synthesize the CNTs (see Patent Document 2). Among the various CNT synthesis processes, the gas-phase CVD process is precluded from using any substrate or carrier, and can be easily scaled up; thus, it is the most suitable process for mass production.

The possibility of wide application of CNTs as a major material in nanotechnology is being researched. The applications of CNTs are classified into an application of a single CNT in a transistor, a microscope probe or the like, and an application of bulk aggregating CNTs.

For the latter one, an application using a mesh of CNTs as a film for a transparent electrically conductive film (Non-patent Document 3) and a biosensor (Non-patent Document 4) is estimated to be promising.

As for the above technologies for producing a CNT film that is useful as an industrial material, an invention for forming a film by dispersing SWCNTs in a solvent and coating the dispersion has been disclosed (Patent Document 3). The CNTs may be dispersed via the following method of placing the CNTs into an aqueous solution containing a surface active agent such as sodium dodecyl sulfate (for example, see Patent Document 4).

Moreover, as for other technologies for forming a film by SWCNT, the following method has also been disclosed in (Non-patent Document 5) about arranging metal particles on a heat-resistant substrate (such as a silicon substrate, a quartz substrate, or a sapphire substrate) to serve as a catalyst, and growing the SWCNTs on the substrate through the substrate CVD process, so as to form a film.

Patent Document 1: Japanese Laid-open Patent Publication No. H7-197325

Patent Document 2: Japanese Laid-open Patent Publication No. 2001-80913

Patent Document 3: Japanese Laid-open Patent Publication No. 2006-176362

Patent Document 4: Japanese Laid-open Patent Publication No. H6-228824 (Pages 5-6)

Non-patent Document 1: “Science”, vol. 273, 1996, p 483

Non-patent Document 2: “Journal of Physical Chemistry B”, vol. 106, 2002 (issued on Feb. 16, 2002), p 2429

Non-patent Document 3: “Journal of Materials Chemistry”, vol. 16, 2006 (issued on Jun. 30, 2006), p 3533

Non-patent Document 4: “Analytical and Bioanalytical Chemistry”, vol. 384, 2006 (issued on Aug. 30, 2005), p 322

Non-patent Document 5: “Journal of Physical Chemistry B”, vol. 109, 2005 (issued on Jan. 22, 2005), p 2632

As disclosed in Patent Document 4, the invention discloses forming a film by dispersing CNTs in a solvent and coating the dispersion. Since the dispersion of CNTs is difficult to achieve, it is challenging to establish a reproducible film-forming technology. Even for the method disclosed in Patent Document 1, in which the CNTs are uniformly dispersed, the problem of impairment in electrical conductivity due to nonconductive organic substances adhering to the surface of the CNTs remains.

Moreover, since a dry process is preferred for electronic devices in most cases, developing a film-forming technology using a dry process is highly anticipated.

On the other hand, even if the dry process is used in the method disclosed in Non-patent Document 5, the following problem remains. Since the reaction temperature for the formation of the SWCNTs is generally equal to or higher than 500° C., only highly heat-resistant substrates are applicable, while polymeric and non-heat-resistant inorganic substrates cannot be used.

### SUMMARY OF THE INVENTION

Accordingly, the present invention is directed to a method and an apparatus for efficiently mass-producing a SWCNT film, which is useful as an industrial material, at low temperature and low cost.

To achieve the objectives, the inventor carried out studies, and identified that a single-wall nanotube film can be obtained by directly depositing a single-wall nanotube synthesized through a gas-phase CVD process on a substrate.

That is, the following inventions are provided.

<1> A method for forming a CNT film is provided. The method includes synthesizing CNTs from a raw material source through a gas-phase CVD process, and directly depositing the synthesized CNTs on a substrate in a chamber connected with a reaction tube; a CNT film is thereby formed on the substrate.

<2> An apparatus for forming a CNT film is provided, which includes a deposition mechanism. The apparatus is characterized in that the deposition mechanism is connected to a reaction tube for synthesizing CNTs from a raw material source through a gas-phase CVD process, and the CNTs are deposited on a substrate.

<3> A CNT film is provided, which is formed by synthesizing CNTs from a raw material source through a gas-phase CVD process, and directly depositing the synthesized CNTs on a substrate in a chamber connected with a reaction tube to form the CNT film on the substrate.

### EFFECT OF THE INVENTION

The method and apparatus for forming a CNT film of the present invention can efficiently mass-produce the CNT film at low cost.

In addition, since the method and apparatus for forming a CNT film of the present invention do not require any dispersion process, a reproducible film-forming technology can be realized.

Furthermore, the method and apparatus for forming a CNT film of the present invention employ a dry process, which is particularly suitable for electronic devices.

Moreover, with the method and the apparatus for forming a CNT film of the present invention, a CNT film is obtained by uniformly depositing CNTs. The CNT film has homogeneous semiconductive, mechanical and optical characteristics. Accordingly, the present invention provides a significant industrial contribution to the electronic field.

### BRIEF DESCRIPTION OF THE DRAWINGS

FIG. 1 is a front view of an apparatus for forming a SWCNT film according to an embodiment of the present invention.

FIG. 2 is cross-sectional front views of examples of a substrate and a Peltier element mounted on a substrate holder.

FIG. 3 is a photograph of a CNT film formed on a soda glass substrate.

FIG. 4 is photographs showing measurement results of the water contact angle for evaluating the hydrophobicity of the formed film, in which FIG. 3(a) shows the result when water is dropped on the film, and FIG. 3(b) shows the result when water is dropped on a quartz substrate.

### DESCRIPTION OF THE SYMBOLS

1: electric furnace

2: mullite reaction tube

3: spray nozzle

4: microfeeder

5: second carbon source

6: carrier gas source

7: mass flow controller of the second carbon source

8: mass flow controller of the first carrier gas

9: mass flow controller of the second carrier gas

10: gas mixer

11: single-walled carbon nanotube

12: chamber

13: casing

14: communicating pipe

15: valve

16: substrate holder

17: substrate

18: outside communication portion

19: port

20: trap

21: Peltier element

22: recess

23: direct current power supply

24: lead wire

### DESCRIPTION OF THE EMBODIMENTS

In the present invention, the “gas-phase CVD process” is defined as “a process for synthesizing a single-walled nanotube in a fluidized vapor phase by atomizing a raw material containing a catalyst (including precursors thereof) and an accelerant with a spray or the like, and introducing the atomized raw material into a high-temperature heating furnace (such as an electric furnace)”.

Below, SWCNT synthesis by the gas-phase CVD process, referred to as enhanced direct injection pyrolytic synthesis, is illustrated as an example for synthesizing CNTs by the gas-phase CVD process. It should be appreciated that the application of the gas-phase CVD process is not particularly limited in the CNT synthesis of the present invention.

In order to synthesize SWCNTs from a carbon source through the enhanced direct injection pyrolytic synthesis, at least two carbon sources are prepared, for example, a hydrocarbon that is liquid at normal temperature used as a first carbon source, and a hydrocarbon that is gaseous at normal temperature used as a second carbon source.

The carbon sources generally refer to “organic compounds containing carbon atoms”.

The hydrocarbon used as the first carbon source is a hydrocarbon that is a liquid at normal temperature and may be any of aromatic and aliphatic hydrocarbons, and is preferably a saturated aliphatic hydrocarbon. The hydrocarbon includes any of acyclic hydrocarbons and cyclic hydrocarbons.

The acyclic saturated aliphatic hydrocarbon that is a liquid at normal temperature includes an alkane compound represented by a general formula CₙH₂ₙ₊₂. Examples of the alkane compound include hexane, heptane, octane, nonane, decane, undecane, dodecane, tridecane, tetradecane, pentadecane, hexadecane, and heptadecane. The first carbon source is preferably n-decane.

Examples of the cyclic saturated aliphatic hydrocarbon include a monocyclic saturated aliphatic hydrocarbon, a bicyclic saturated aliphatic hydrocarbon, and a condensed ring saturated aliphatic hydrocarbon, etc. The first carbon source used in the present invention has to be liquid at normal temperature. Examples of the cyclic saturated aliphatic hydrocarbon include cyclohexane, decahydronaphthalene (including cis-decahydronaphthalene, trans-decahydronaphthalene, and mixtures thereof), and tetradecahydrophenanthrene. The first carbon source is preferably decahydronaphthalene.

The hydrocarbon used as the second carbon source is a hydrocarbon that is gaseous at normal temperature, and is preferably an unsaturated aliphatic hydrocarbon. The hydrocarbon, gaseous at normal temperature, is preferably a hydrocarbon that thermally decomposes at a temperature lower than the hydrocarbon used as the first carbon source.

Examples of the unsaturated aliphatic hydrocarbon include ethylene and propylene having a double bond and acetylene having a triple bond, etc. The second carbon source is preferably ethylene or acetylene, and more preferably ethylene.

The carbon sources are resulted from appropriately combining the first carbon source and the second carbon source. However, in view of the decomposition temperature and the reaction controllability of the first carbon source and the second carbon source, when decahydronaphthalene is used as the first carbon source, the second carbon source—is preferably ethylene, acetylene or the like having a thermal decomposition temperature lower than decahydronaphthalene.

In addition, a ratio of the first carbon source to the second carbon source is determined according to the diameter of the target SWCNT. When the ratio is a volume ratio of the first carbon source to the second carbon source, (volume of second carbon source)/(volume of first carbon source), at room temperature, the ratio is 1 to 1.0×10⁵, preferably 15 to 6.3×10⁴, and more preferably 1.0×10² to 1.0×10⁴.

If the ratio is greater than 1.0×10⁵, it is difficult to form the SWCNT; and if the ratio is smaller than 1, it is difficult to realize the flow control of the second carbon source and homogeneous reaction.

Furthermore, with respect to the method of introducing the first carbon source and the second carbon source into a reactor, in view of the control of the side reaction, the second carbon source should not be introduced before the first carbon source. Preferably, the first carbon source and the second carbon source are simultaneously introduced into the reactor.

The flow rate in this case is not particularly limited, and may be appropriately selected according to the volume and the shape of the reactor, the flow rate of the carrier gas, and the like.

Furthermore, the first carbon source and the second carbon source are preferably introduced into a reactor together with the carrier gas to ensure a rapid homogeneous reaction.

As the carrier gas, the conventionally known hydrogen or an inert gas containing hydrogen is preferably used.

A ratio of the carrier gas to the first carbon source, which is a volume ratio of the first carbon source to the carrier gas, (volume of first carbon source)/(volume of carrier gas), at room temperature is 5.0×10⁻⁸ to 1.0×10⁻⁴, and preferably 1.0×10⁻⁷ to 1.0×10⁻⁵.

When the SWCNTs are synthesized, for example, the catalyst, the accelerant, the first carbon source, the second carbon source and preferably a carrier gas are respectively supplied, or a raw material mixture obtained by mixing these raw materials is supplied to a reaction region maintained at a temperature of 800° C. to 1200° C. in the reactor.

The catalyst used in the present invention is not particularly limited in terms of the type and form of metal; however, a transition metal compound or transition metal ultrafine particles are preferably used.

The transition metal compound is decomposed in the reactor to form transition metal fine particles as a catalyst. The transition metal compound is preferably supplied in the state of a gas or a metal cluster to a reaction region maintained at a temperature of 800° C. to 1200° C. in the reactor.

Examples of the transition metal atom include iron, cobalt, nickel, scandium, titanium, vanadium, chromium and manganese, etc. Here, iron, cobalt and nickel are preferably used.

Examples of the transition metal compound include an organic transition metal compound and an inorganic transition metal compound, etc. Examples of the organic transition metal compound include ferrocene, cobaltocene, nickelocene, iron carbonyl, iron acetylacetonate, and iron oleate, etc. Ferrocene is preferably used. Examples of the inorganic transition metal compound include iron chloride, etc.

A sulfur compound is preferably used as the accelerant according to the present invention. The sulfur compound contains sulfur atoms and interacts with the transition metal serving as the catalyst, thereby promoting the formation of the SWCNT.

Examples of the sulfur compound include an organic sulfur compound and an inorganic sulfur compound, etc. Examples of the organic sulfur compound include sulfur-containing heterocyclic compounds such as thianaphthene, benzothiophene and thiophene, etc. Thiophene is preferably used. Examples of the inorganic sulfur compound include hydrogen sulfide.

According to the synthesizing method, SWCNTs having a diameter of preferably 1.0 nm to 2.0 nm can be obtained.

A mechanism connected to the reaction tube for synthesizing the SWCNTs and used for depositing the SWCNTs on a substrate includes: a casing, having a chamber in communication with an inner portion of an outlet of the reaction tube; communicating pipes, capable of communicating an inner portion of the casing with the outside through an ON-OFF valve (gate valve); a substrate holder, freely inserted from the outside into the casing through the communicating pipes or unplugged from the casing; and a substrate, mountable on the substrate holder.

The substrate is formed with, for example, an inorganic material such as a silicon wafer, glass, sapphire and sintered alumina, etc., or made of an organic material such as polyimide, polyester, polyethylene, polyphenylene sulfide, polyparaxylene, polycarbonate and polyvinyl chloride, etc. Substrates constructed with organic materials have low heat resistance; however, they may still be used as the substrate as long as the temperature of the substrate holder is set to be equal to or lower than the melting point of the material. Here, even if no particular treatment for improving the substrate surface aside from a substrate cleaning process, the CNTs may be deposited on the substrate according to the present invention. Silicon oxide substrates such as silicon wafers, glass substrates and the like may be treated by a surface modifier such as a silane coupling agent to improve the compatibility with the CNTs. A substrate that has been subjected to the aforementioned surface treatment may also be applied in the present invention for forming the film more efficiently.

### Embodiments

Embodiments of the present invention are illustrated below with reference to the accompanying drawings. In addition, the following embodiments are provided in order for the present invention to be comprehensible, and are not intended to limit the present invention. It is understood that variations, embodiments and other examples made based on the technical ideas of the present invention should also fall within the scope of the present invention.

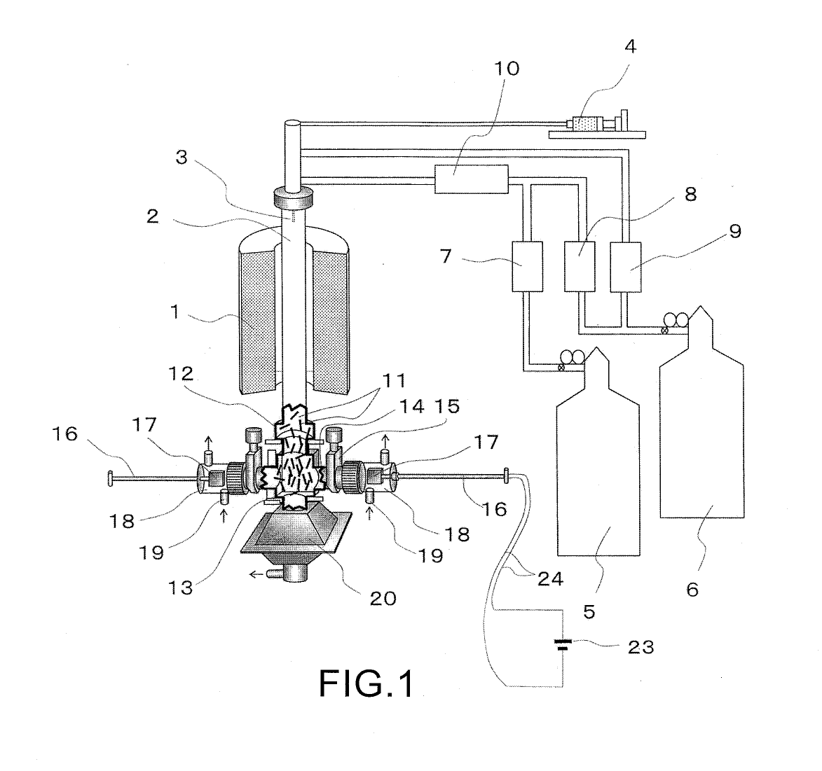

FIG. 1 is a front view of an apparatus for forming a SWCNT film according to an embodiment of the present invention, the essential parts of the apparatus are shown in a cross section.

The part in the apparatus for synthesizing SWCNTs 11 includes an electric furnace 1, a mullite reaction tube 2, a spray nozzle 3, a microfeeder 4, a second carbon source 5, a carrier gas source 6, a mass flow controller of the second carbon source 7, a mass flow controller of the first carrier gas 8, a mass flow controller of the second carrier gas 9, and a gas mixer 10.

The microfeeder 4 stores a raw material liquid containing decahydronaphthalene serving as the first carbon source, ferrocene serving as the organic transition metal compound, and thiophene serving as the organic sulfur compound mixed by weight at a ratio of 100:4:2. In addition, ethylene is used as the second carbon source 5, and the flow rate is controlled through the mass flow controller of the second carbon source 7 and the gas mixer 10.

In addition, in the apparatus, a deposition mechanism connected to the reaction tube 2 for synthesizing the SWCNTs and used for depositing the SWCNTs 11 on a substrate includes: a casing 13, having a chamber 12 in communication with an inner portion of an outlet of the reaction tube 2; a pair of left and right communicating pipes 14, capable of communicating an inner portion of the casing 13 with the outside; valves 15, for opening or closing passages of the communicating pipes 14; substrate holders 16, freely inserted from the outside into the casing 13 through the communicating pipes 14 or unplugged from the casing 13; and a substrate 17 and a Peltier element 21, mountable on the substrate holder 16. The substrate 17 is a quartz substrate or a soda glass substrate.

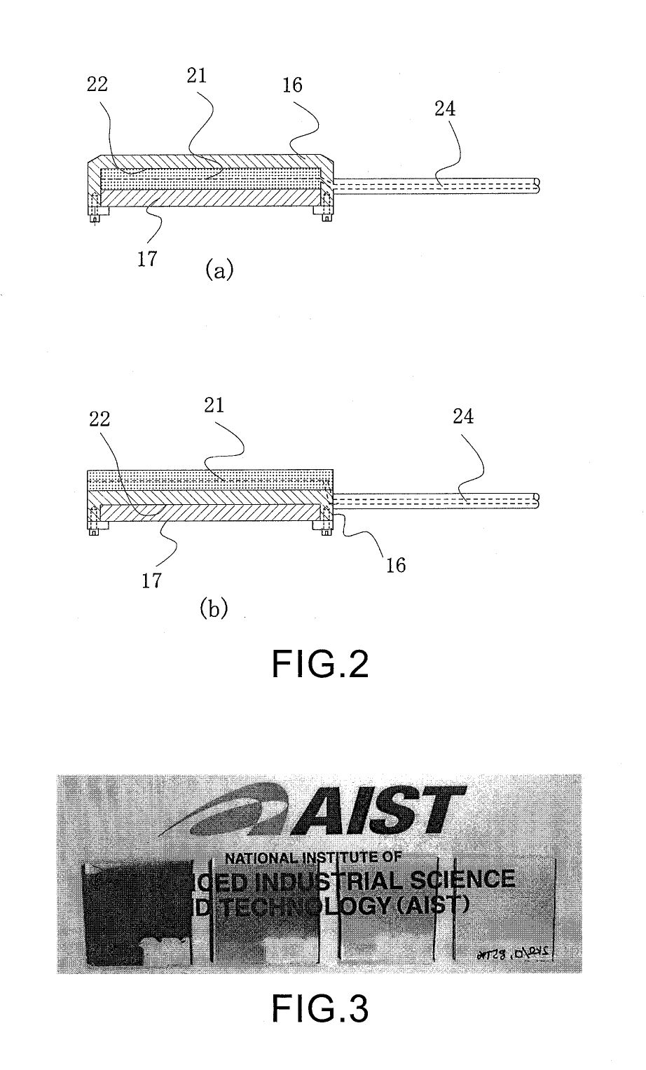

FIG. 2 shows examples of the substrate 17 and the Peltier element 21 mounted on the substrate holder 16.

Referring to FIG. 2(a), the Peltier element 21 is disposed in a recess 22 of the substrate holder 16 supporting the substrate 17 and contacts a back surface of the substrate 17. A heat-absorbing surface of the Peltier element 21 is directly connected to the back surface of the substrate 17, so as to cool down the substrate 17.

Referring to FIG. 2(b), the Peltier element 21 contacts the back surface of the substrate holder 16 supporting the substrate 17. The heat-absorbing surface of the Peltier element 21 contacts the back surface of the substrate holder 16, so as to cool down the substrate 17.

The Peltier element 21 is connected to a direct current (DC) power supply 23 shown in FIG. 1 through lead wires 24.

Regarding the substrate holder 16 and the communicating pipes 14, when the longitudinal-mode gas-phase CVD process is applied as the synthesis process, no space is provided at the bottom of the apparatus in most cases. Hence, the substrate is preferably arranged perpendicular to the gas flow containing the SWCNTs 11 that flows downward from the reaction tube 2 so as to move perpendicularly, which is relative to the longitudinal direction of the reaction tube 2. However, if a space is being provided, the substrate is preferably arranged to be movable in a direction parallel to the longitudinal direction. An outside communication portion 18 of the communicating pipes 14 is formed with transparent components, such that the substrate 17 can be observed from the outside when the substrate holder 16 is removed from the chamber 12 of the casing 13. An exit is formed on the outside communication portion 18, such that the substrate 17 can be removed through the exit. In addition, ports 19 for gas replacement are disposed at two positions of the outside communication portion 18. In this embodiment, the experiment is carried out after gas replacement by argon gas.

Regarding the valve 15, a conventional gate valve is used. The valve 15 opens the passages of the communicating pipes 14 when the substrate 17 is inserted into the chamber 12 in the casing 13, and closes the passages of the communicating pipes 14 when the substrate 17 is removed from the chamber 12.

A trap 20 is connected downstream from the casing 13, and traps the SWCNTs 11 that are not provided for film-forming on the substrate 17.

Next, the formation of the synthesized SWCNTs 11 into a film in the apparatus is illustrated.

CNTs 11 are formed in the reaction tube 2, and transported into the chamber 12. Air in a space surrounding the valve 15 and the substrate holder 16 is replaced by argon gas in advance. Then, the valve 15 is opened, and the substrate 17 is inserted into the chamber 12 in a direction parallel to the longitudinal direction of the reaction tube 2. Considering that the CNTs 11 are dispersed in the gas flow in the reaction tube 2 in the form of aerosols, and the CNTs 11 are oriented in the direction of the gas flow when the gas flow is close to a laminar flow, the substrate 17 is arranged in a laminar flow region inside the reaction tube 2, so that a film of the CNTs 11 oriented in the direction of the gas flow is deposited thereon. As the temperature decreases, the gas flow becomes turbulent, a non-directional irregular film is deposited if the substrate 17 is arranged in the region. At this time, no matter which direction the substrate 17 is arranged relative to the direction of the gas flow, the same film is deposited. Accordingly, the CNTs 11 can be deposited on the substrate 17 without requiring a particular parallel arrangement, and any direction is acceptable. The adhesion of the CNTs 11 to the substrate 17 is resulted from the intermolecular force, such as the van der waals force interacting between the substrate 17 and the CNTs 11. That is, the CNTs 11 are deposited on the surface of the substrate 17 due to the small roughness on the surface of the substrate 17, or electrostatic interactions caused by the substrate 17 in an electrified state.

FIG. 3 is a photograph of a CNT film formed on a soda glass substrate. The thickness of the film can be changed by setting the position of the substrate during the deposition operation of the CNTs at the upstream or at the downstream. The closer the film is to the upstream, the higher the film-forming speed is (from left to right in the photograph). The film-forming speed can also be changed according to the time of the deposition operation or the amount of the CNTs formed.

To evaluate the formed film, resonance Raman spectra were measured (NRS-2100, manufactured by JASCO Inc., using argon laser 514.5 nm excitation light). A distinct vibration mode of the SWCNT called radial breathing mode was observed near 148.5 cm⁻¹, indicating that a film of SWCNTs is formed.

Similarly, to evaluate the film, measurement of optical absorption spectrum (UV3150, manufactured by Shimadzu Corporation) was carried out. Three peaks were observed at 2300 nm, 1250 nm, 800 nm in the optical absorption spectrum, namely, a first electronic excitation (band gap) S1 and a second electronic excitation S2 of semiconductor SWCNTs, and a first electronic transition M1 of metal SWCNTs.

Likewise, to evaluate the film, measurement of transmittance at 550 nm (UV3150, manufactured by Shimadzu Corporation) and measurement of surface resistance (low-resistivity meter MCP-T600, manufactured by Mitsubishi Chemical Corporation) were carried out. When the transmittance is 85%, the surface resistance of the film is 2 Ω/□.

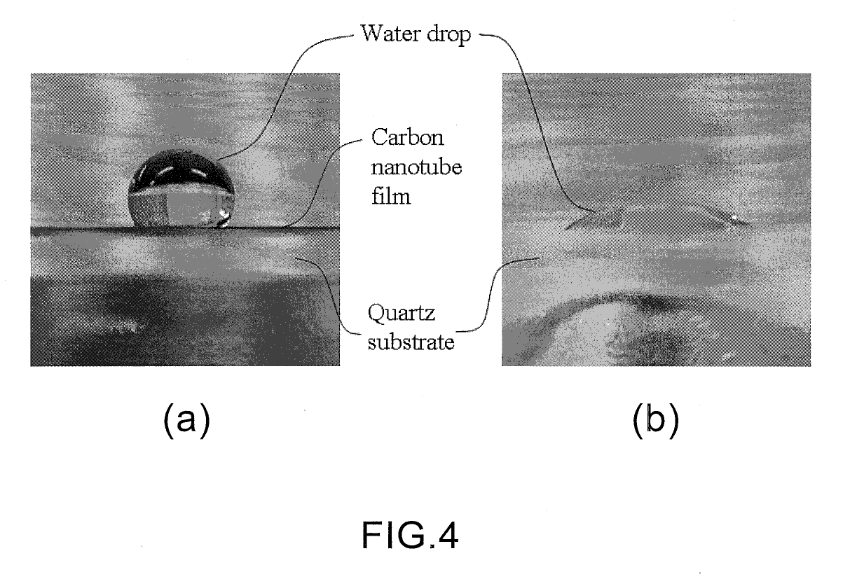

To evaluate the hydrophobicity of the formed film, measurement of the water contact angle was carried out. FIG. 4(a) is a photograph of the test. A 5 μL water drop was placed on the film, and the contact angle is measured to be 145°.

For comparison, measurement of the contact angle on a quartz substrate was carried out, and the contact angle is measured to be 36.6° . FIG. 4(b) is a photograph of the test.

### INDUSTRIAL APPLICABILITY

Applications of the CNTs can be categorized into an application of a single CNT in a transistor, a microscope probe or the like, and a bulk application by aggregating CNTs.

For the bulk application, the method for using CNTs to form a film can be used in practice for producing a transparent electrically conductive film or a biosensor.

1. A method for forming a carbon nanotube (CNT) film, wherein CNTs are synthesized from a raw material source through a gas-phase chemical vapor deposition (CVD) process, and the synthesized CNTs are directly deposited on a substrate of a device, in which the substrate has been cooled to 200° C. or less in a chamber connected with a reaction tube to directly form a CNT film on the substrate of the device.

2. An apparatus for forming a carbon nanotube (CNT) film, comprising a chamber connected with a reaction tube for synthesizing CNTs from a raw material source through a gas-phase chemical vapor deposition (CVD) process, wherein the CNTs are directly deposited on a substrate of a device and the substrate has been cooled to 200° C. or less using a cooling mechanism in the chamber.

3. A carbon nanotube (CNT) film, formed by synthesizing CNTs from a raw material source through a gas-phase chemical vapor deposition (CVD) process, and directly depositing the synthesized CNTs on a substrate, which has been cooled to 200° C. or less in a chamber connected with a reaction tube, of a device, to directly form a CNT film on the substrate of the device.
